(19) United States
(12) Patent Application Publication
(10) Pub. No.: US 2025/0033097 A1
(43) Pub. Date: Jan. 30, 2025

(54) APPARATUS AND METHOD OF CLEANING COMPONENT

(71) Applicant: SEMES CO., LTD., Cheonan-si (KR)

(72) Inventors: Byung Woo SIM, Yongin-si (KR); Bok Kyu LEE, Cheonan-si (KR)

(73) Assignee: SEMES CO., LTD., Cheonan-si (KR)

(21) Appl. No.: 18/758,101

(22) Filed: Jun. 28, 2024

(30) Foreign Application Priority Data
Jul. 26, 2023 (KR) 10-2023-0097371

(51) Int. Cl. B08B 3/14; F26B 3/02

(52) U.S. Cl. CPC B08B 3/14; F26B 3/02; B08B 2203/007

(57) ABSTRACT

Disclosed is an apparatus for cleaning a component, the apparatus including: a cleaning fluid supply source; a supply line for receiving cleaning fluid from the cleaning fluid supply source and connected with a first port of the component; a discharge line connected with a second port of the component; and a circulation line branched from the discharge line and connected with a third port of the component.

### CROSS-REFERENCE TO RELATED APPLICATIONS

This application claims priority to and the benefit of Korean Patent Application No. 10-2023-0097371 filed in the Korean Intellectual Property Office on Jul. 26, 2023, the entire contents of which are incorporated herein by reference.

### TECHNICAL FIELD

The present invention relates to an apparatus for processing a substrate.

### BACKGROUND ART

A semiconductor device manufacturing process is the process of forming a circuit pattern on a substrate, such as a wafer, to complete a chip. The semiconductor device process includes a deposition process to form a thin film on a substrate, a photo lithography process to transfer a circuit pattern onto the thin film by using a photo mask, an etching process to selectively remove unnecessary portions by using chemical substances or reactive gas to form the desired circuit pattern on the substrate, ashing process to remove the remaining photoresist after etching, and ion implantation process to inject ions into the portions that are connected to the circuit pattern to give the characteristics of an electronic device. In each process, and between processes, a cleaning process is performed to remove contaminants from the substrate.

The device that performs each process requires a supply line to supply the chemical solution or gas, and the supply line is equipped with components, such as valves and filters. The components may accumulate foreign substances therein over time, so that a regular cleaning is required.

### SUMMARY OF THE INVENTION

The present invention has been made in an effort to provide an apparatus and a method of cleaning a component that are capable of effectively removing foreign substances inside a component.

The present invention has also been made in an effort to provide an apparatus and a method of cleaning a component that are capable of effectively removing foreign substances inside each port in a three-way valve.

The present invention has also been made in an effort to provide an apparatus and a method of cleaning a component that are capable of simultaneously removing foreign substances inside components of different types, such as filters and valves.

The object of the present invention is not limited thereto, and other objects not mentioned will be clearly understood by those of ordinary skill in the art from the following description.

An exemplary embodiment of the present invention provides an apparatus for cleaning a component, the apparatus including: a cleaning fluid supply source; a supply line for receiving cleaning fluid from the cleaning fluid supply source and connected with a first port of the component; a discharge line connected with a second port of the component; and a circulation line branched from the discharge line and connected with a third port of the component.

According to the exemplary embodiment, the apparatus may further include: a supply valve installed in the supply line; and a regulating valve unit provided for selectively regulating drainage from the discharge line to the outside and circulation to the circulation line. The regulating valve unit may include a three-way valve installed at a point where the circulation line is branched from the discharge line.

According to the exemplary embodiment, the apparatus may further include a controller for controlling the supply valve and the regulating valve unit, in which the controller may control the supply valve and the regulating valve unit so that cleaning fluid supplied from the supply line passes sequentially through the first port, the second port, the discharge line, the circulation line, the third port, the second port, and the discharge line.

According to the exemplary embodiment, the cleaning fluid supply source may include: a cleaning solution supply unit that supplies a cleaning solution to the supply line; and a rinse solution supply unit that supplies a rinse solution to the supply line. The cleaning solution supply unit may include: a first supply unit that supplies a rinse solution at a first temperature; and a second supply unit that supplies a rinse solution at a second temperature lower than the first temperature.

According to the exemplary embodiment, the cleaning fluid supply source may further include a gas supply unit that supplies drying gas to the supply line. The gas supply unit may include: a first supply unit that supplies drying gas at a first temperature; and a second supply unit that supplies drying gas at a second temperature higher than the first temperature. The gas supply unit may include: a first gas line that is connected to the supply line and provides drying gas to the supply line; and a second gas line that is connected to the circulation line and provides drying gas to the circulation line.

According to the exemplary embodiment, the supply line may include: a first line connected with a first port of the other component; and a second line connected with a second port of the other component, and the second line is connected with the first port of the component. The other component may be a filter, and the component may be a three-way valve.

Another exemplary embodiment of the present invention provides a method of cleaning a component by using a component cleaning apparatus including a cleaning fluid supply source, a supply line for receiving cleaning fluid from the cleaning fluid supply source and connected with a first port of a component, a discharge line connected with a second port of the component, and a circulation line branched from the discharge line and connected with a third port of the component, the method including: a cleaning preparation operation of connecting the component with the supply line, the discharge line, and the circulation line; and a cleaning operation in which a cleaning solution supplied from the supply line sequentially passes through the first port, the second port, the discharge line, the circulation line, the third port, the second port, and the discharge line to clean the component.

According to the exemplary embodiment, the method may further include a rinsing operation of rinsing the component with a rinse solution supplied from the supply line. The rinsing operation may include: a first operation of rinsing the component with a rinse solution at a first temperature; and after the first operation, a second operation of cooling the component with a rinse solution at a second temperature lower than the first temperature.

According to the exemplary embodiment, the method may further include a drying operation of drying the component with drying gas supplied from the supply line. The drying operation may include: a first operation of drying the component with drying gas at a first temperature, and after the first operation, a second operation of drying the component with drying gas at a second temperature higher than the first temperature.

According to the exemplary embodiment, in the drying operation, the drying gas may be supplied to each of the circulation line and the supply line.

According to the exemplary embodiment, it is possible to effectively remove foreign substances inside the component.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating a component cleaning apparatus according to an exemplary embodiment of the present invention.

FIG. 2 is a diagram illustrating a cleaning target component mounted on the component cleaning apparatus of FIG. 1.

FIG. 3 is a diagram schematically illustrating a component cleaning apparatus according to another exemplary embodiment of the present invention.

FIG. 4 is a diagram schematically illustrating a component cleaning apparatus according to still another exemplary embodiment of the present invention.

FIG. 5 is a flowchart schematically illustrating a component cleaning method according to an exemplary embodiment of the present invention.

FIGS. 6 and 7 are diagrams illustrating a cleaning fluid that is supplied to a component in the component cleaning apparatus of FIG. 1.

FIG. 8 is a diagram illustrating drying gas that is supplied to a component in the component cleaning apparatus of FIG. 1.

FIG. 9 is a diagram schematically illustrating a component cleaning apparatus according to still yet another exemplary embodiment of the present invention.

FIGS. 10 and 11 are diagrams illustrating a cleaning fluid that is supplied to a component in the component cleaning apparatus of FIG. 9.

FIG. 12 is a diagram illustrating drying gas that is supplied to a component in the component cleaning apparatus of FIG. 9.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

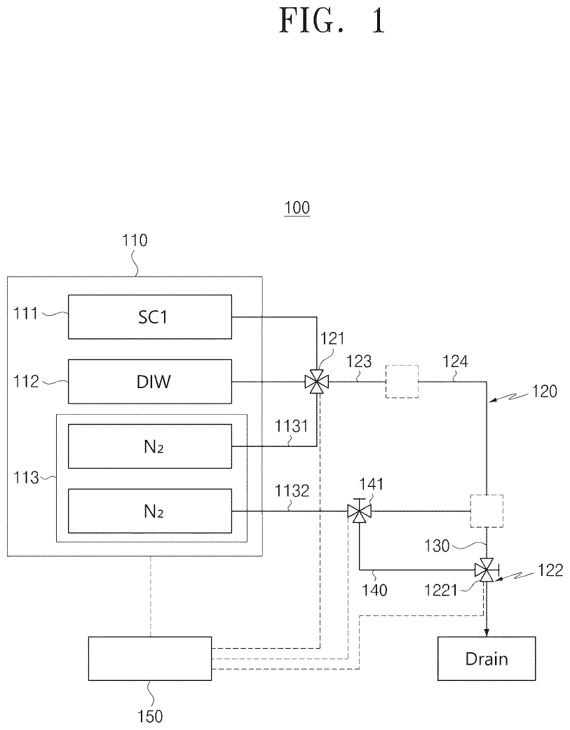

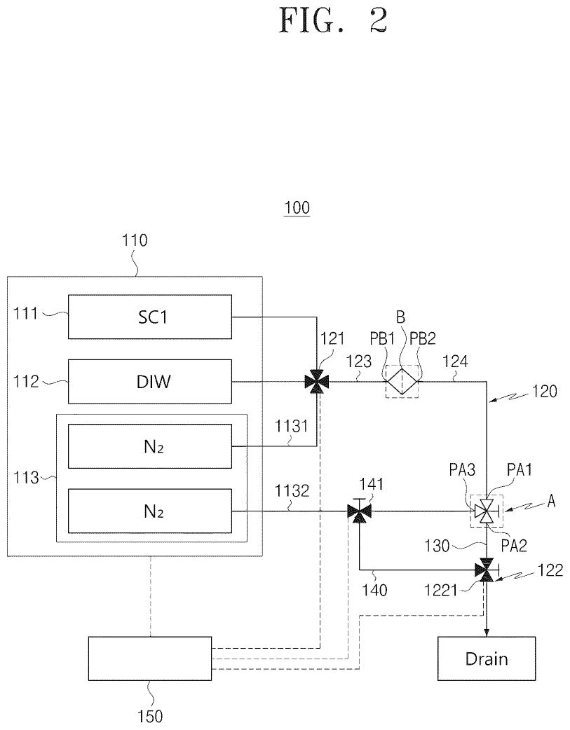

FIG. 1 is a diagram schematically illustrating a component cleaning apparatus according to an exemplary embodiment of the present invention. FIG. 2 is a diagram illustrating a cleaning target component mounted on the component cleaning apparatus of FIG. 1.

Referring to FIGS. 1 and 2, a component cleaning apparatus 100 includes a cleaning fluid supply source 110, a supply line 120, a discharge line 130, a circulation line 140, and a controller 150.

The component cleaning apparatus 100 cleans the interior of components A and B.

The cleaning fluid supply source 110 may include a cleaning solution supply unit 111, a rinse solution supply unit 112, and a gas supply unit 113. The cleaning fluid supplied from the cleaning fluid supply source 110 may be a cleaning solution to clean the component, a rinse solution to rinse the component, gas to dry the component, and the like.

The cleaning solution supply unit 111 supplies the supply line 120 with a cleaning solution to clean the interior of the components A and B. The cleaning solution is not limited to any particular type, and may be Standard Clean-1 (SC1), as illustrated in the drawings as one example. SC1 is a mixture of ammonia, hydrogen peroxide, and water in a ratio of 1:1:5 and is used to remove particles and organic contaminants at a temperature of 75 to 90° C.

The rinse solution supply unit 112 supplies a rinse solution to the supply line 120 to rinse the interior of the components A and B. The rinse solution is not limited to any particular type, and may be deionized water (DIW), as illustrated in one example. The rinse solution supply unit 112 may be provided to supply a rinse solution at various temperatures. For example, the rinse fluid supply unit 112 may include a heater and may be provided to supply a rinse solution at a first temperature and a rinse solution at a second temperature that is lower than the first temperature.

When the rinse solution is DIW, the first temperature may range from 30° C. to 70° C. or more, and the second temperature may range from 10° C. to 30° C. or less.

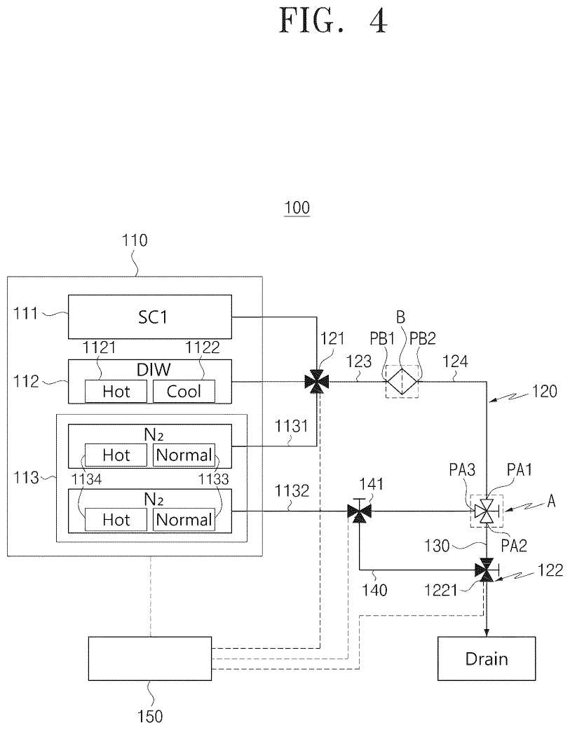

Optionally, the rinse solution supply unit 112 may include a first supply unit 1121 for supplying a rinse solution at a first temperature, and a second supply unit 1122 for supplying a rinse solution at a second temperature lower than the first temperature, as illustrated in FIG. 4.

The gas supply unit 113 supplies gas to the supply line 120 to dry the interior of the components A and B. The gas is not limited to any particular type, and may be nitrogen, as illustrated in the drawings as one example. The gas supply unit 113 may be provided to supply gas of various temperatures. For example, the gas supply unit 113 may include a heater and may be provided to supply gas at a first temperature of gas and gas at a second temperature of gas that is higher than the first temperature.

When the drying gas is nitrogen, the first temperature may be 50° C. or lower, and the second temperature may range from 50° C. to 110° C.

Optionally, the gas supply unit 113 may include a first supply unit 1133 that supplies gas at a first temperature, and a second supply unit 1134 that supplies gas at a second temperature lower than the first temperature as illustrated in FIG. 4.

The gas supply unit 113 may include a first gas line 1131 that supplies gas to the supply line 120 and a second gas line 1132 that supplies gas to the circulation line 140.

In one example, two components A and B of different types may be mounted simultaneously so that the two components may be cleaned simultaneously.

Between the two components, one component A has a first port PA1, a second port PA2, and a third port PA3, and the other component B has a first port PB1 and a second port PB2. Hereinafter, one component A is referred to as a first component, and the other component B is referred to as a second component.

The first component A may be a three-way valve. The second component B may be a filter.

The supply line 120 receives a cleaning fluid from the cleaning fluid supply source 210 and is to the first port P1 of the first component A.

The supply line 120 is equipped with the second component B. The supply line 120 includes a first line 123 and a second line 124. The first line 123 is disposed upstream of the second line 124. The first line 123 may be provided to be connectable with the first port PB1 of the other component B. The second line 124 may be provided to be connectable to each of the second port PB2 of the second component B and the first port PA1 of the first component A. The discharge line 130 may be provided to be connectable with the second port PA2 of the first component A.

The circulation line 140 may be branched from the discharge line 130 and may be provided to be connectable with the third port PA3 of the first component A.

The supply line 120 is equipped with a supply valve 121 that opens and closes the supply line 120. A regulating valve unit 122 is installed in the discharge line 130 and the circulation line 140. The supply valve 121 is located near the cleaning fluid supply source 110 to control whether the cleaning fluid is supplied and the amount of cleaning fluid supplied.

The regulating valve unit 122 regulates the cleaning fluid entering the first port PA1 of the three-way valve that is the first component A to flow in a direction selected between drainage from the discharge line 130 to the outside and circulation to the circulation line 140. The regulating valve unit 122 may be a three-way valve 1221 installed at a point where the circulation line 140 is branched from the discharge line 130.

At the connection point of the second gas line 1132 and the circulation line 140, a three-way valve 141 may be provided to selectively regulate the circulation of the cleaning fluid and the supply of gas.

Optionally, the regulating valve unit 122 may include a two-way valve (not illustrated) installed in the discharge line 130 as an alternative to the three-way valve 1221, and a two-way valve (not illustrated) installed in the circulation line 140.

The controller 150 controls the operation of the cleaning fluid supply source 110 and the various valves 121, 122, and 141.

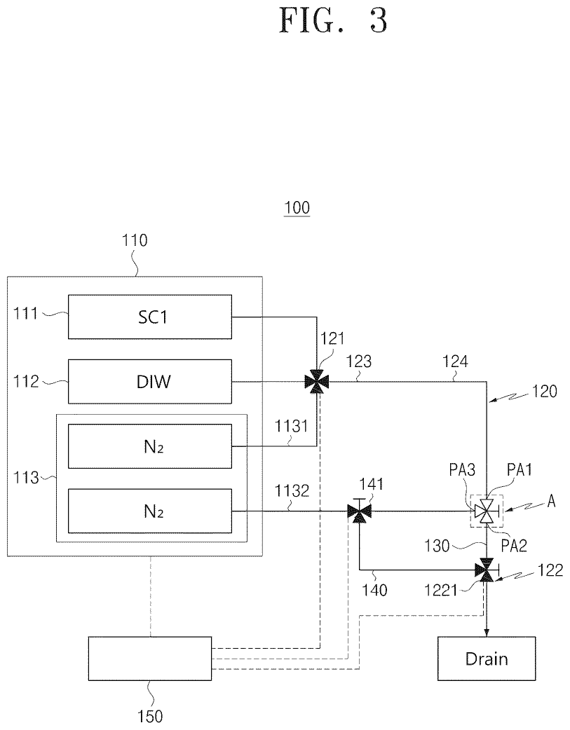

In the example described above, it has been described that the two components are cleaned simultaneously. In contrast, however, as illustrated in FIG. 3, the component cleaning apparatus 100 may be provided to clean only the first component A having three ports.

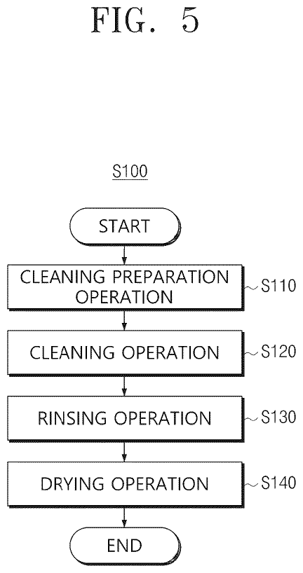

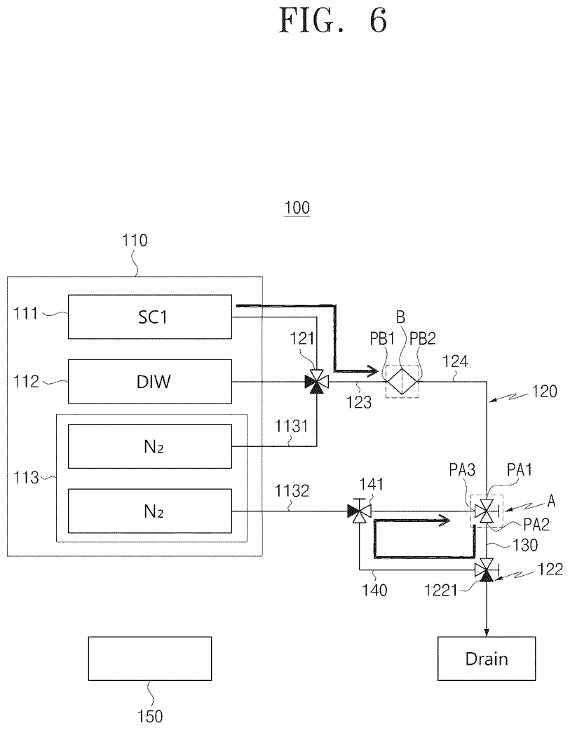

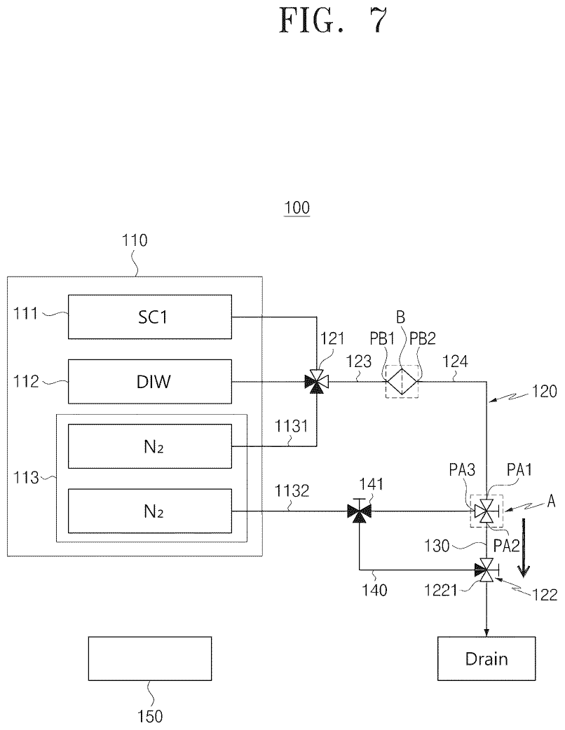

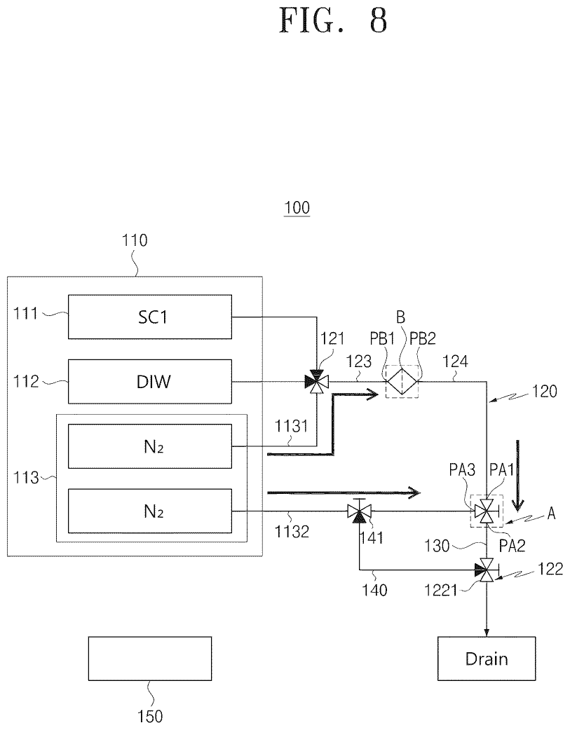

FIG. 5 is a flowchart schematically illustrating a component cleaning method according to an exemplary embodiment of the present invention. FIGS. 6 and 7 are diagrams illustrating a cleaning fluid that is supplied to a component in the component cleaning apparatus of FIG. 1, and FIG. 8 is a diagram illustrating drying gas that is supplied to a component in the component cleaning apparatus of FIG. 1.

Referring to FIGS. 5 to 8, a component cleaning method S100 includes a cleaning preparation operation S110, a cleaning operation S120, a rinsing operation 130, and a drying operation S140.

In the cleaning preparation operation S110, the first component A to be cleaned is mounted on the supply line 120, the discharge line 130, and the circulation line 140. The first port PA1 of the first component A is connected to the supply line 120, the second port PA2 of the first component A is connected to the discharge line 130, and the third port PA3 of the first component A is connected to the circulation line 140.

The second component B to be cleaned is mounted on the first line 123 and second line 124 of the supply line 120. The first port PB1 of the second component B is connected to the first line 123, and the second port PB2 of the second component B is connected to the second line 124.

In the cleaning operation S120, a cleaning solution is supplied from the cleaning fluid supply source 110 to clean the interior of the components A and B. The valve unit is controlled so that the cleaning solution flows sequentially through the first port PB1 of the second component B, the second port PB2 of the second component B, the first port PA1 of the first component A, the second port PA2 of the first component A, the discharge line 130, the circulation line 140, the third port PA3 of the first component A, the second port PA2 of the first component A, and the discharge line 130. This allows all three ports PA1, PA2, and PA3 of the first component A to be cleaned. In addition, the two ports PB1 and PB2 of the second component B may also be cleaned. The cleaning with the cleaning solution may be performed for a set time.

In the rinsing operation S130, a rinse solution is supplied from the cleaning fluid supply source 110 to rinse the interior of the components A and B. The valve unit is controlled so that the rinse solution flows sequentially through the first port PB1 of the second component B, the second port PB2 of the second component B, the first port PA1 of the first component A, the second port PA2 of the first component A, the discharge line 130, the circulation line 140, the third port PA3 of the first component A, the second port PA2 of the first component A, and the discharge line 130. This allows all three ports PA1, PA2, and PA3 of the first component A to be rinsed. In addition, the two ports PB1 and PB2 of the second component B may also be rinsed. The rinsing with the rinse solution may be performed for a set time.

The rinsing operation S130 may include a first operation of rinsing the components A and B with a rinse solution at a first temperature, and a second operation of cooling the components A and B with a rinse solution at a second temperature lower than the first temperature. In this case, the cooling may restore the condition of the components A and B, which may reduce damage to the product in the drying operation S140 and increase the drying effectiveness.

When the rinse solution is DIW, the first temperature may range from 30° C. to 70° C. or more, and the second temperature may range from 10° C. to 30° C. or less.

In the drying operation S140, drying gas is supplied from the cleaning fluid supply source 110 to dry the interior of the components A and B. The drying gas may be supplied to each of the supply line 120 and the circulation line 130. Specifically, drying gas may be supplied to the first gas line 1131 and the second gas line 1132. In this case, the drying gas flow inside the first component A is improved. Specifically, the vortices generated inside the first component A prevent the formation of dead zones where the gas flow stagnates, and the first component A is completely dried.

The drying operation S140 may include a first operation of drying the components A and B with drying gas at a first temperature, and a second operation of cooling the components A and B with drying gas at a second temperature higher than the first temperature.

When the drying gas is nitrogen, the first temperature may be 50° C. or lower, and the second temperature may range from 50° C. to 110° C.

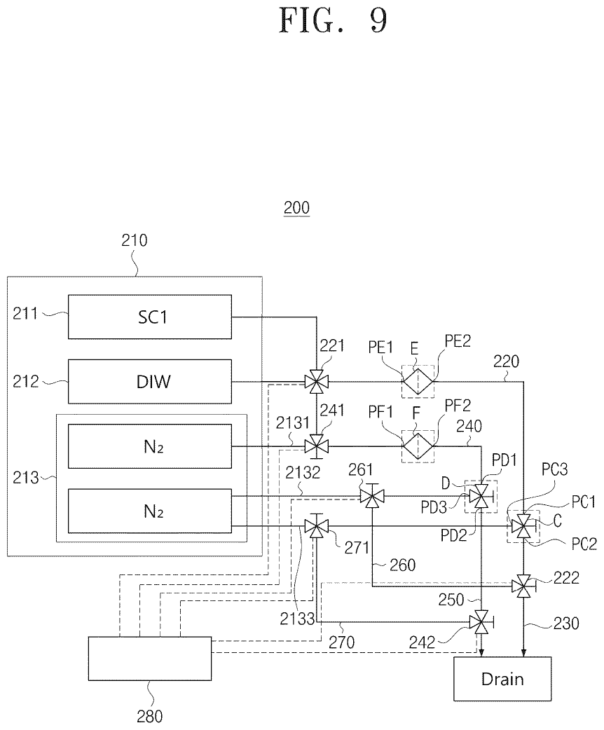

FIG. 9 is a diagram schematically illustrating a component cleaning apparatus according to still yet another exemplary embodiment of the present invention.

Referring to FIG. 9, a component cleaning apparatus 200 includes a cleaning fluid supply source 210, a first supply line 220, a first discharge line 230, a second supply line 240, a second discharge line 250, a first circulation line 260, a second circulation line 270, and a controller 280.

The component cleaning device 200 cleans the interior of components C, D, E, and F, and the like.

Two components C and D of the four components have first ports PC1 and PD1, second ports PC2 and PD2, and third ports PC3 and PD3, and the other two components D and F have first ports PD1 and PF1 and second ports PD2 and PF2.

Hereinafter, the two components C and D are referred to as a third component C and a fourth component D, and the other two components E and F are referred to as a fifth component E and a sixth component F.

The third component C and the fourth component D may be three-way valves, and the fifth component E and the sixth component F may be filters.

The cleaning fluid supply source 210 may include a cleaning solution supply unit 211, a rinse solution supply unit 212, and a gas supply unit 213. The cleaning fluid supplied from the cleaning fluid supply source 210 may be a cleaning solution to clean the component, a rinse solution to rinse the component, gas to dry the component, and the like.

The first supply line 220 receives the cleaning fluid from the cleaning fluid supply source 210 and is connected to the first port PCI of the third component C. The first supply line 220 may be provided with a supply valve 221 for opening and closing the first supply line 220.

The first discharge line 230 is connected to the second port PC2 of the third component C.

The second supply line 240 receives the cleaning fluid from the cleaning fluid supply source 210 and is connected to the first port PD1 of the fourth component D. The second supply line 240 may be provided with a supply valve 241 for opening and closing the second supply line 240.

The second discharge line 250 is connected to the second port PD2 of the fourth component D.

The first circulation line 260 is branched from the first discharge line 230 and is connected to the third port PD3 of the fourth component D. At the point where the first circulation line 260 is branched from the first discharge line 230, a regulating valve unit 222 may be provided. The regulating valve unit 222 may include a three-way valve.

The second circulation line 270 is branched from the second discharge line 250 and is connected to the third port PC3 of the third component C. At the point where the second circulation line 270 is branched from the second discharge line 250, a regulating valve unit 242 may be provided. The regulating valve unit 242 may include a three-way valve.

Optionally, the first supply line 220 and the second supply line 240 may be provided for the fifth component E and the sixth component F to be installed.

Optionally, the gas supply unit 213 may include a first gas line 2131 supplying drying gas to the first supply line 220 and the second supply line 240, a second gas line 2132 supplying drying gas to the first circulation line 260, and a third gas line 2133 supplying drying gas to the second circulation line 270.

Three-way valves 261 and 271 may be provided at the point where the first circulation line 260 and the second gas line 2132 are connected and at the point where the second circulation line 270 and the third gas line 2133 are connected.

The controller 280 controls the operation of the cleaning fluid supply source 210 and the various valves 221, 222, 241, 242, 261, and 271.

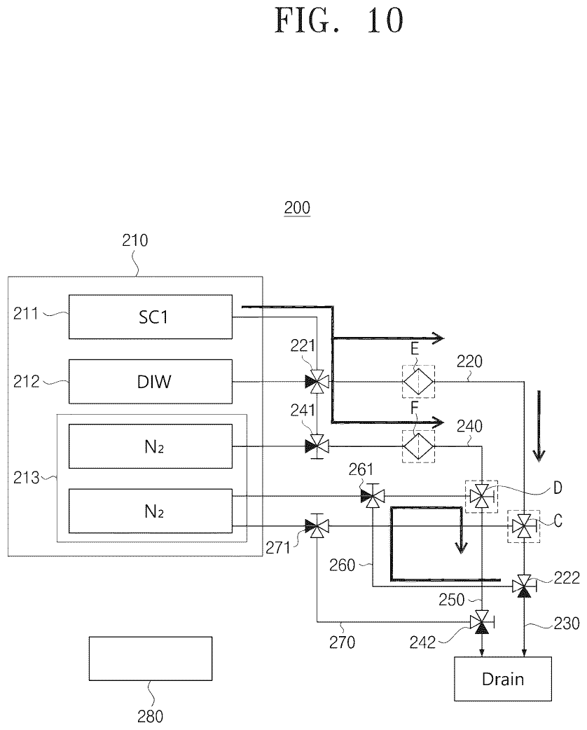

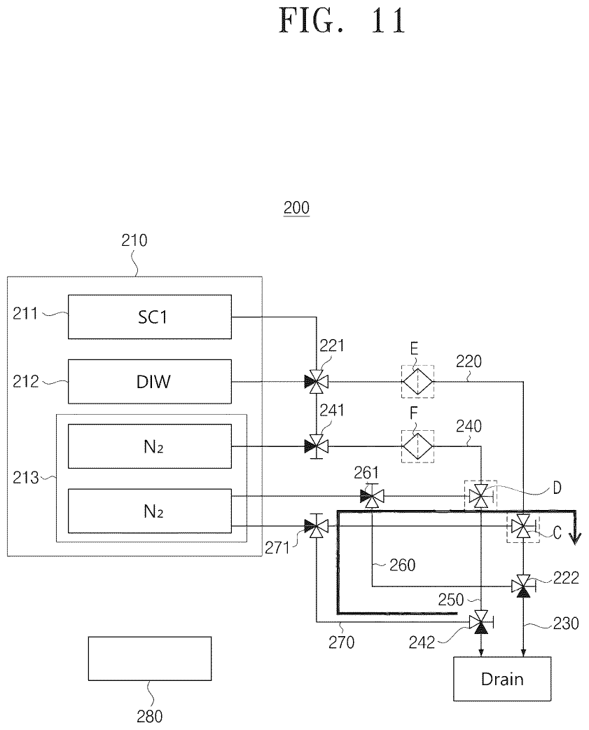

Referring to FIGS. 10 and 11, the cleaning fluid supplied by the cleaning fluid supply source 210 may be discharged while passing through the first supply line 220, the first port PC1 of the third component C, the second port PC2 of the third component C, the first discharge line 230, and the first circulation line 260, the third port PD3 of the fourth component D, the second port PD2 of the fourth component D, the second discharge line 250, the second circulation line 270, the third port PC3 of the third component C, the second port PC2 of the third component C, and the first discharge line 230, and first circulation line 260. In this case, the path of travel for the cleaning fluid is increased, thereby efficiently cleaning the components C and D with a small amount of cleaning fluid.

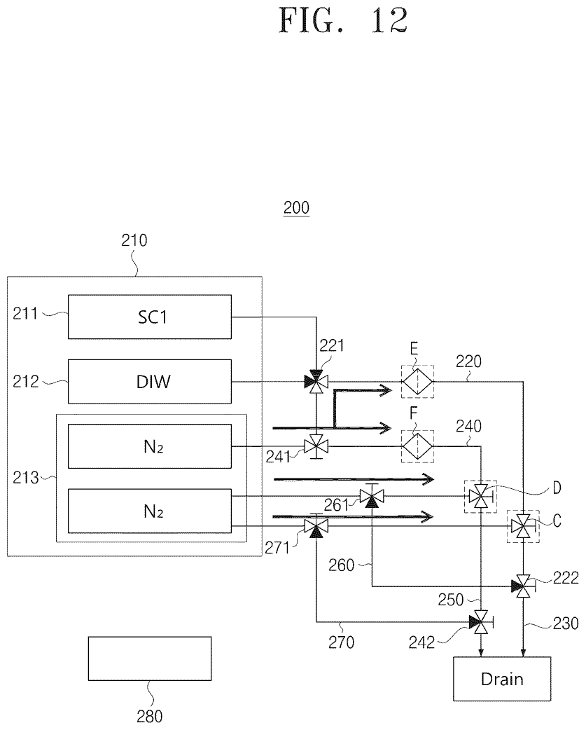

Referring to FIG. 12, the gas supply unit 213 may be provided to simultaneously supply drying gas to the first gas line 2131, the second gas line 2132, and the third gas line 2133. In this case, the drying gas flow inside the third component C and the fourth component D is improved. Specifically, the vortices generated inside Parts C and D prevent the formation of dead zones where the gas flow stagnates, the third component C and the fourth component D are completely dried.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

1. An apparatus for cleaning a component, the apparatus comprising:
a cleaning fluid supply source;
a supply line for receiving cleaning fluid from the cleaning fluid supply source and connected with a first port of the component;
a discharge line connected with a second port of the component; and
a circulation line branched from the discharge line and connected with a third port of the component.

2. The apparatus of claim 1, further comprising:
a supply valve installed in the supply line; and
a regulating valve unit provided for selectively regulating drainage from the discharge line to the outside and circulation to the circulation line.

3. The apparatus of claim 2, wherein the regulating valve unit includes a three-way valve installed at a point where the circulation line is branched from the discharge line.

4. The apparatus of claim 2, further comprising:
a controller for controlling the supply valve and the regulating valve unit,
wherein the controller controls the supply valve and the regulating valve unit so that cleaning fluid supplied from the supply line passes sequentially through the first port, the second port, the discharge line, the circulation line, the third port, the second port, and the discharge line.

5. The apparatus of claim 1, wherein the cleaning fluid supply source includes:
a cleaning solution supply unit that supplies a cleaning solution to the supply line; and
a rinse solution supply unit that supplies a rinse solution to the supply line.

6. The apparatus of claim 5, wherein the cleaning solution supply unit includes:
a first supply unit that supplies a rinse solution at a first temperature; and
a second supply unit that supplies a rinse solution at a second temperature lower than the first temperature.

7. The apparatus of claim 5, wherein the cleaning fluid supply source further includes a gas supply unit that supplies drying gas to the supply line.

8. The apparatus of claim 7, wherein the gas supply unit includes:
a first supply unit that supplies drying gas at a first temperature; and
a second supply unit that supplies drying gas at a second temperature higher than the first temperature.

9. The apparatus of claim 7, wherein the gas supply unit includes:
a first gas line that is connected to the supply line and provides drying gas to the supply line; and
a second gas line that is connected to the circulation line and provides drying gas to the circulation line.

10. The apparatus of claim 1, wherein the supply line includes:
a first line connected with a first port of the other component; and
a second line connected with a second port of the other component, and
the second line is connected with the first port of the component.

11. The apparatus of claim 10, wherein the other component is a filter, and the component is a three-way valve.

12.-17. (canceled)

18. An apparatus for cleaning a first component and a second component each having a first port, a second port, and a third port, the apparatus comprising:
a cleaning fluid supply source;
a first supply line for receiving cleaning fluid from the cleaning fluid supply source and connected with the first port of the first component;
a first discharge line connected with the second port of the first component;
a second supply line for receiving cleaning fluid from the cleaning fluid supply source and connected with the first port of the second component;
a second discharge line connected with the second port of the second component;
a first circulation line branched from the first discharge line and connected with the third port of the second component; and
a second circulation line branched from the second discharge line and connected with the third port of the first component.

19. The apparatus of claim 18, wherein the cleaning fluid supply source includes:
a cleaning solution supply unit that supplies a cleaning solution to the supply line; and
a rinse solution supply unit that supplies a rinse solution to the supply line.

20. The apparatus of claim 18, wherein the cleaning liquid supply source includes a gas supply unit, and
the gas supply unit includes:
a first gas line that supplies drying gas to the first supply line and the second supply line;
a second gas line that supplies drying gas to the first circulation line; and
a third gas line that supplies drying gas to the second circulation line.
